(19) United States
(12) Patent Application Publication
(10) Pub. No.: US 2026/0173979 A1
(43) Pub. Date: Jun. 18, 2026

(54) CHIP AND MANUFACTURING AND ENCAPSULATION METHOD THEREFOR

(71) Applicant: CANAAN CREATIVE (SH) CO., LTD., Shanghai (CN)

(72) Inventors: Zhongyi Han, Shanghai (CN); Nangeng Zhang, Shanghai (CN)

(73) Assignee: CANAAN CREATIVE (SH) CO., LTD., Jing'an District (CN)

(21) Appl. No.: 19/126,222

(22) PCT Filed: Oct. 31, 2023
(86) PCT No.: PCT/CN2023/128156

§ 371 Date: Apr. 30, 2025

(30) Foreign Application Priority Data
Oct. 31, 2022 (CN) 202211365836.2
Sep. 22, 2023 (CN) 202311234978.X

(51) Int. Cl. H10W 90/00

(52) U.S. Cl. CPC H10W 90/724; H10W 90/734

(57) ABSTRACT

The present invention provides a chip and a manufacturing and encapsulation method therefor. The chip comprises: a substrate, and an intermediate layer arranged on the substrate, and further comprises: a first die, which is disposed above the intermediate layer and is manufactured on the basis of a first process technique accommodating the function of the at least one first die; and a second die, which is disposed above the intermediate layer and is manufactured on the basis of a second process technique accommodating the function of the at least one second die, wherein the at least one second die and the at least one first die are interconnected by means of the intermediate layer. By means of the chip, the costs can be reduced and the yield can be improved while achieving a chip effect.

This application claims the priority of Chinese patent application No. 202211365836.2, filed on Oct. 31, 2022, entitled “CHIP PACKAGING METHOD AND CHIP”, and claims the priority of Chinese patent application No. 202311234978.X, filed on Sep. 22, 2023, entitled “CHIP, AND MANUFACTURING AND PACKAGING METHODS THEREFOR”, the disclosures of which are incorporated herein by reference.

### TECHNICAL FIELD

The present disclosure pertains to the field of packaging process, and particularly relates to a chip, and manufacturing and packaging methods therefor.

### BACKGROUND

This section is intended to provide background or context for the embodiments of the present disclosure as set forth in claims. What is described herein is not admitted as prior art merely by virtue of its inclusion in this section.

In conventional technical solutions for chips, chip manufacturing is typically implemented using a single fabrication process and a single packaging approach. For high performance computing chip designs, the extreme computational density leads to significantly elevated power consumption. Therefore, the most advanced process nodes are typically adopted to leverage process benefits, thereby reducing power consumption. However, in fact, not all functions on one chip need to be implemented through the most advanced processes.

As the cost of advanced processes increases significantly, the manufacturing cost of chips is also rising. With the advancement of processes, the rate of decrease in transistor cost has declined sharply, and the increase in chip area has also led to a decrease in chip yield.

Therefore, how to achieve a balance between chip performance, cost and yield is an urgent problem to be solved.

### SUMMARY

In view of the aforementioned problems existing in the prior art, the present disclosure proposes a hybrid packaging method for a chip, and a hybrid-packaged chip, by using which those problems can be solved.

The present disclosure provides the following solutions.

In a first aspect, a chip is provided, including a substrate an interposer disposed above the substrate, and further including: at least one first die disposed above the interposer, the at least one first die being fabricated based on a first fabrication process accommodating a function of the at least one first die; and at least one second die disposed above the interposer, the at least one second die being fabricated based on a second fabrication process accommodating a function of the at least one second die, where the at least one first die and the at least one second die are interconnected through the interposer.

In one embodiment, the at least one first die is packaged based on a first packaging process accommodating the function of the at least one first die, and the at least one second die is packaged based on a second packaging process accommodating the function of the at least one second die.

In one embodiment, the at least one first die is configured for a computation function.

In one embodiment, the at least one second die is configured for an auxiliary function.

In one embodiment, the at least one second die includes one or more of: a control-function die configured for chip control; a test-function die configured for chip testing; and an interface-function die configured to enable an I/O interface.

In one embodiment, a fabrication process accommodating each function of die is positively correlated with a first performance demand for said each function of die, where the first performance demand includes at least one of demands on rate, power consumption, and bandwidth.

In one embodiment, a packaging process accommodating each function of die is positively correlated with a second performance demand for said each function of die, where the second performance demand includes at least one of demands on rate and bandwidth.

In one embodiment, the at least one first die is stacked on the interposer based on the first packaging process, and the at least one second die is tiled on the interposer based on the second packaging process.

In one embodiment, the interposer includes a main portion disposed on the upper side of the substrate and a branch portion extended along a direction in which a plurality of dies are stacked; the at least one first die is stacked on the upper side of the main portion, and each of the at least one first die is laterally extended to be connected to the branch portion.

In one embodiment, the interposer is an inverted T-shaped interposer.

In one embodiment, the first packaging process is a 3D packaging process or an advanced packaging process beyond the 3D packaging process, and the second packaging process is a 2.5D packaging process.

In a second aspect, a manufacturing method for a chip is provided, including: forming an interposer above a substrate; forming at least one first die above the interposer, the at least one first die being fabricated based on a first fabrication process accommodating a function of the at least one first die; forming at least one second die above the interposer, the at least one second die being fabricated based on a second fabrication process accommodating a function of the at least one second die; and interconnecting the at least one first die and the at least one second die through the interposer.

In one embodiment, the at least one first die is packaged based on a first packaging process accommodating the function of the at least one first die, and the at least one second die is packaged based on a second packaging process accommodating the function of the at least one second die.

In one embodiment, the at least one first die is configured for a computation function.

In one embodiment, the at least one second die is configured for an auxiliary function.

In one embodiment, the at least one second die includes one or more of: a control-function die configured for chip control; a test-function die configured for chip testing; and an interface-function die configured to enable an I/O interface.

In one embodiment, a fabrication process accommodating each function of die is positively correlated with a first performance demand for said each function of die, where the first performance demand includes at least one of demands on rate, power consumption, and bandwidth.

In one embodiment, a packaging process accommodating each function of die is positively correlated with a second performance demand for said each function of die, where the second performance demand includes at least one of demands on rate and bandwidth.

In one embodiment, the method further includes: stacking the formed at least one first die on the interposer based on the first packaging process; and tiling the formed at least one second die on the interposer based on the second packaging process.

In one embodiment, the interposer includes a main portion disposed on an upper side of the substrate and a branch portion extended along a direction in which a plurality of dies are stacked, where the at least one first die is stacked on an upper side of the main portion and laterally extended to be connected to the branch portion.

In one embodiment, the interposer is an inverted T-shaped interposer.

In one embodiment, the first packaging process is a 3D packaging process or an advanced packaging process beyond the 3D packaging process, and the second packaging process is a 2.5D packaging process.

In a third aspect, a hybrid packaging method for a chip is provided, including: partitioning a chip into multiple blocks according to respective functions; determining respective fabrication processes according to first computation demands for the multiple blocks; fabricating the multiple blocks into a plurality of dies through the respective fabrication processes; determining respective packaging processes corresponding to the multiple blocks for the plurality of dies at least according to second computation demands for the multiple blocks; and resembling and interconnecting the plurality of dies through the respective packaging processes.

In one embodiment, the multiple blocks include a computation block for implementing integrated computation, and a functional block for implementing an auxiliary function.

In one embodiment, the method further includes: when the computation block includes multiple computing cores, further partitioning the computation block to obtain multiple computation sub-blocks respectively corresponding to the multiple computing cores.

In one embodiment, the functional block includes one or more of: a control block for chip control; a test block for chip testing; and an interface block for enabling an I/O interface.

In one embodiment, a first computation demand for each block includes one or more of demands on rate, power consumption, and bandwidth.

In one embodiment, a second computation demand for each block includes a demand on rate and/or a demand on bandwidth.

In one embodiment, determining the respective packaging processes corresponding to the multiple blocks for the plurality of dies includes: determining the respective packaging processes according to a size of each die and/or a packaging complexity for resembling and interconnecting the plurality of dies.

In one embodiment, the method further includes: stacking more than one die corresponding to multiple first blocks on an upper side of the interposer through a first packaging process; tile one or more dies corresponding to one or more second blocks on an upper side of the interposer through a second packaging process; and establishing interconnections between dies through the interposer connected to the substrate.

In one embodiment, the first packaging process is a 3D packaging process and/or an advanced packaging process beyond the 3D packaging process, and the second packaging process is a 2.5D packaging process.

In one embodiment, the method further includes: utilizing a special-shaped interposer, where the special-shaped interposer has a main portion disposed on the upper side of the substrate and a branch portion extended along a direction in which the more than one die is stacked, the more than one die corresponding to the first blocks are stacked on the upper side of the main portion and laterally extended to be connected to the branch portion.

In one embodiment, the special-shaped interposer is an inverted T-shaped interposer.

In one embodiment, the chip is a high-computing power chip.

In a fourth aspect, a hybrid packaged chip is provided, including a chip obtained through the method according to the second or third aspect.

In a fifth aspect, a hybrid packaged chip is provided, including a substrate, an interposer disposed above the substrate, and a plurality of dies disposed above the interposer; where the plurality of dies are fabricated through different fabrication processes, and resembled and interconnected above the interposer through different packaging processes.

In one embodiment, the plurality of dies correspond to multiple blocks partitioned according to respective functions in the chip, where the plurality of dies are fabricated through different fabrication processes according to the first computation demands for the corresponding blocks, and resembled and interconnected above the interposer through different packaging processes according to the second computation demands for the corresponding blocks.

In one embodiment, the fabrication process for each die is determined according to one or more of demands on rate, power consumption, and bandwidth for the corresponding block of each die.

In one embodiment, the packaging process for each die is determined according to one or more of a demand on rate and/or a demand on bandwidth of the corresponding block of each die, a size of each die, and a packaging complexity for resembling and interconnection.

In one embodiment, the multiple blocks include a computation block for implementing integrated computing and a functional block for implementing auxiliary functions.

In one embodiment, when the computation block includes multiple computing cores, the computation block is further partitioned to obtain multiple computation sub-blocks corresponding to the multiple computing cores.

In one embodiment, the functional block includes one or more of a control block for chip control; a test block for chip testing; and an interface block for enabling an I/O interface.

In one embodiment, for the plurality of dies resembled and interconnected above the interposer through different packaging processes, more than one die is stacked on the upper side of the interposer through a first packaging process; and/or one or more dies are tiled on the upper side of the interposer through a second packaging process; and interconnections between dies are established through the interposer connected to the substrate.

In one embodiment, the first packaging process is a 3D packaging process and/or an advanced packaging process beyond the 3D packaging process, and the second packaging process is a 2.5D packaging process.

In one embodiment, a special-shaped interposer is utilized, where the special-shaped interposer has a main portion disposed on the upper side of the substrate and a branch portion extended along a direction in which more than one die are stacked, the more than one die being stacked on the upper side of the main portion, and extended laterally to be connected to the branch portion.

In one embodiment, the special-shaped interposer is an inverted T-shaped interposer.

In one embodiment, the chip is a high-computing power chip.

One of the advantages of the aforementioned embodiments lies in that a large monolithic chip is partitioned into smaller dies, followed by integrating multiple homogeneous or heterogeneous dies into a unified design through an improved advanced packaging architectures, such that for distinct blocks, more suitable fabrication and packaging processes for dies are applied and interconnections between dies are implemented with improved efficiency respectively, thereby improving the computing power of the manufactured chip, and achieving balanced optimization across bandwidth density, latency, power consumption, and cost thereof, thus capitalizing on the benefits of reduced bandwidth density, power consumption, and cost, while effectively mitigating the need for continuous die size scaling.

Other advantages of the present disclosure will be explained in more detail with the following description and drawings.

It should be understood that the above description is merely an overview of the technical solutions of the present disclosure, intended to provide a general understanding of the technical means disclosed herein, thereby facilitating implementation in accordance with the contents of the specification. To render the above and other objectives, features and advantages of the present disclosure more apparent and comprehensible, specific embodiments are provided below to illustrate the detailed implementations of the present disclosure.

### BRIEF DESCRIPTION OF THE DRAWINGS

Through reading the detailed description of the exemplary embodiments below, a person of ordinary skill in the art would understand the advantages and benefits described herein and other advantages and benefits. The drawings are only for the purpose of illustrating exemplary embodiments and are not intended to be limitations to the present disclosure. Moreover, the same reference characters are used throughout the drawings to represent the same components. In the drawings:

FIG. 1 is a schematic structural diagram of a chip according to an embodiment of the present disclosure;

FIG. 2 is a schematic structural diagram of a chip according to another embodiment of the present disclosure;

FIG. 3 is a schematic structural diagram of a chip according to yet another embodiment of the present disclosure;

FIG. 4 is a schematic flow chart of a manufacturing method for a chip according to an embodiment of the present disclosure.

FIG. 5 is a schematic flow chart of a hybrid packaging method for a chip according to an embodiment of the present disclosure;

FIG. 6 is a schematic structural diagram of a hybrid-packaged chip according to an embodiment of the present disclosure;

FIG. 7 is a schematic structural diagram of a hybrid-packaged chip according to an embodiment of the present disclosure;

FIG. 8 is a schematic structural diagram of a hybrid-packaged chip according to an embodiment of the present disclosure;

FIG. 9 is a schematic structural diagram of a hybrid-packaged chip according to an embodiment of the present disclosure;

FIG. 10 is a schematic structural diagram of a hybrid-packaged chip according to an embodiment of the present disclosure;

In the accompanying drawings, the same or corresponding reference numerals represent the same or corresponding parts.

### DETAILED DESCRIPTION

The exemplary embodiments of the present disclosure will be described in more detail below with reference to the accompanying drawings. Although the exemplary embodiments of the present disclosure are shown in the accompanying drawings, it should be understood that the present disclosure can be implemented in various forms and should not construed as limited to the embodiments described herein. Rather, these embodiments are provided to enable a more thorough understanding of the present disclosure and to fully convey the scope of the present disclosure to a person of ordinary skill in the art.

In the description of the embodiments of the present disclosure, it should be understood that terms such as “including” or “having” are intended to indicate the existence of the disclosed features, numerals, steps, actions, components, parts, or any combination thereof in the specification, without excluding the existence of one or more other features, numerals, steps, actions, components, parts, or any combination thereof.

Unless otherwise specified, “/” denotes “or”. For example, “A/B” may indicate A or B. The term “and/or” herein merely describes the associative relationship between associated objects, indicating that three possible relationships may exist. For example, “A and/or B” may indicate: A alone, A and B together, or B alone.

Terms such as “first”, “second”, etc. are used solely to distinguish similar or identical technical features for ease of description and should not be interpreted as indicating or implying relative importance or quantity of the features. Thus, features modified by “first”, “second”, etc., may explicitly or implicitly include one or more such features. In the description of the embodiments of the present disclosure, unless otherwise specified, the term “plurality” means two or more.

To clarify the embodiments of the present disclosure, certain technical concepts that may be referenced in subsequent embodiments shall first be defined.

Chiplet: A multifunctional heterogeneous system-in-package (SiP) chip formed by packaging multiple module dies together with an underlying base die through die-to-die internal interconnect technologies.

Packaging: The process of assembling integrated circuits into final chip products.

Through Silicon Vias (TSV): An electrical connection penetrating through the full thickness of a die, providing the shortest path between opposing sides.

Interposer: A silicon-based substrate made of silicon and organic materials, configured to connect the upper and lower layers via TSVs and soldered to the traditional 2D packaging substrate through solder balls. In advanced packaging architectures, it serves as an electrical conduit for multi-chip modules to route electrical signals.

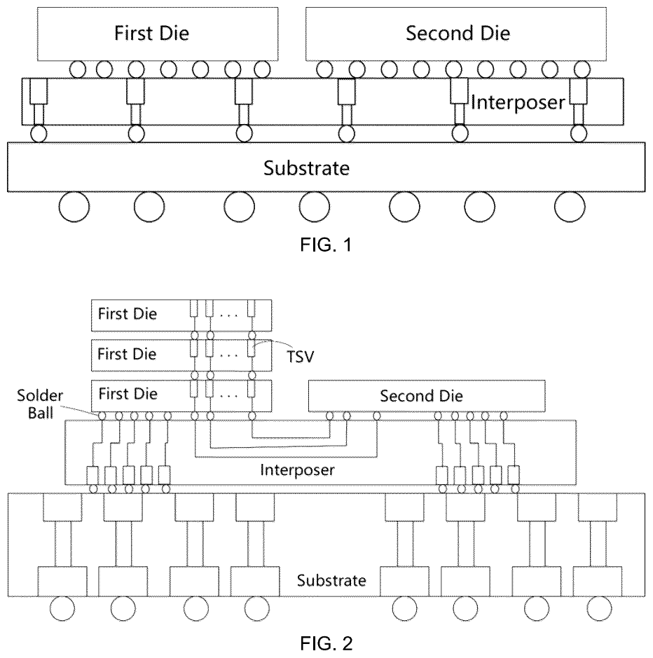

Referring to FIG. 1, an embodiment of the present disclosure provides a chip, which includes:
a substrate;
an interposer disposed above the substrate;
a first die disposed above the interposer, the first die being fabricated based on a first fabrication process that accommodates a function of the first die; and
a second die disposed above the interposer, the second die being fabricated based on a second fabrication process that accommodates a function of the second die,
where the first die and the second die are interconnected through the interposer.

Specifically, the fabrication process corresponding to each die may be proportional to its functional demand, that is, the higher the functional demand, the more advanced the adopted fabrication process. The functional demand may include various aspects such as bandwidth, rate, and power consumption.

For example, referring to FIG. 1, it is assumed that the function of the first die is large-scale integrated computation, and thus requirements for performances such as interconnection bandwidth, rate, and power consumption are very high. In this case, a more advanced fabrication process such as TSMC's 5 nm process may be chosen for fabrication. Furthermore, stdcell such as ELVT may be adopted to enhance the chip's speed and reduce power consumption. Unlike the first die, the second die has no special requirement on rate in its functional design, but the overall chip power consumption needs to be considered, thus it may be fabricated through a less advanced fabrication process such as TSMC's 7 nm. Alternatively, a more stable and mature fabrication process such as Samsung's 14 nm and SMIC's 12 nm may be chosen.

It can be understood that a plurality of dies corresponding to multiple fabrication processes may be integrated on the chip, not limited to two types of dies. This embodiment is described only by taking the first die and the second die as an example.

In this embodiment, a large monolithic chip is partitioned into smaller dies, followed by integrating multiple homogeneous or heterogeneous dies into a unified design through an improved advanced packaging architectures, such that for distinct blocks, more suitable fabrication and packaging processes for dies are applied and interconnections between dies are implemented with improved efficiency respectively, thereby improving the computing power of the manufactured chip, and achieving balanced optimization across bandwidth density, latency, power consumption, and cost thereof, thus capitalizing on the benefits of reduced bandwidth density, power consumption, and cost, while effectively mitigating the need for continuous die size scaling.

In one embodiment, a chip is provided, which includes:
a substrate;
an interposer disposed above the substrate;
a first die disposed above the interposer, the first die being fabricated based on a first fabrication process that accommodates a function of the first die; and
a second die disposed above the interposer, the second die being fabricated based on a second fabrication process that accommodates a function of the second die, the first die and the second die being interconnected through the interposer,
where the first die is packaged based on a first packaging process that accommodates its function; and the second die is packaged based on a second packaging process that accommodates its function.

For example, a 2.5D packaging process may be adopted to package a die with a lower computation demand for saving cost, and a 3D packaging process or a more advanced packaging process (for example, 4D packaging, 5D packaging) may be adopted to package the other die with a higher computation demand for achieving better technical effects. By adopting hybrid packaging approach, different benefits of various packaging methods can be fully utilized.

The present disclosure embodiment does not specifically restrict the packaging processes for the first and second dies, and any differentiated packaging processes that meet chip packaging requirements may be adopted.

In one embodiment, a chip is provided, which includes:
a substrate;
an interposer disposed above the substrate;
a first die disposed above the interposer, the first die being fabricated based on a first fabrication process that accommodates a function of the first die; and
a second die disposed above the interposer, the second die being fabricated based on a second fabrication process that accommodates a function of the second die, the first die and the second die being interconnected through the interposer,
where the first die is configured for a computation function. It can be understood that the computation function typically requires higher performance, which can facilitate the migration of the die configured for the computation function to advanced fabrication and packaging processes.

In the above embodiment, the second die is configured for an auxiliary function. It can be understood that the auxiliary function typically requires lower performance, which allows the die configured of the auxiliary function to remain on more conservative fabrication and packaging processes to save cost and improve yield.

In one embodiment, a chip is provided, which includes:
a substrate;
an interposer disposed above the substrate;
a first die disposed above the interposer, the first die being fabricated based on a first fabrication process that accommodates a function of the first die; and
a second die disposed above the interposer, the second die being fabricated based on a second fabrication process that accommodates a function of the second die, the first die and the second die being interconnected through the interposer,
where the second die is configured for an auxiliary function. It can be understood that the auxiliary function typically requires lower performance, which allows the die configured of the auxiliary function to remain on a more conservative fabrication and packaging processes to save cost and improve yield.

In one embodiment, a chip is provided, which includes:
a substrate;
an interposer disposed above the substrate;
a first die disposed above the interposer, the first die being fabricated based on a first fabrication process that accommodates a function of the first die; and
at least one second die disposed above the interposer, the at least one second die being fabricated based on a second fabrication process that accommodates a function of the at least one second die, the first die and the at least one second die being interconnected through the interposer,
where the at least one second die includes one or more of: a control-function die configured for chip control; a test-function die configured for chip testing; and an interface-function die configured to enable an I/O interface. It can be understood that the control-function die, the test-function die, and the interface-function die are all functional chips with relatively low requirements for computation, thus a more conservative fabrication and packaging processes may be adopted without affecting the actual use effect.

Optionally, the control-function die, the test-function die, and the interface-function die in the at least one second die may adopt differentiated fabrication and packaging processes based on different computation demands. For example, unlike the computation block, the control-function die has no special requirement on rate in design, but the overall chip power consumption needs to be considered, thus a relatively moderate fabrication process may be adopted. In contrast, the test-function die and the interface-function die have much lower demands on computation, thus a more stable and mature fabrication process may be chosen.

In one embodiment, a chip is provided, which includes:
a substrate;
an interposer disposed above the substrate;
a first die disposed above the interposer, the first die being fabricated based on a first fabrication process that accommodates a function of the first die; and
a second die disposed above the interposer, the second die being fabricated based on a second fabrication process that accommodates a function of the second die, the first die and the second die being interconnected through the interposer,
where the first die is packaged based on a first packaging process accommodating its function, and the second die is packaged based on a second packaging process accommodating its function, the first die being configured for a computation function. It can be understood that the computation function typically requires higher performance, which can facilitate the migration of the die configured for the computation function to an advanced fabrication and packaging processes.

In one embodiment, a chip is provided, which includes:
a substrate;
an interposer disposed above the substrate;
a first die disposed above the interposer, the first die being fabricated based on a first fabrication process that accommodates a function of the first die; and
a second die disposed above the interposer, the second die being fabricated based on a second fabrication process that accommodates a function of the second die, the first die and the second die being interconnected through the interposer,
where the first die is packaged based on a first packaging process accommodating its function, and the second die is packaged based on a second packaging process accommodating its function, the first die being configured for a computation function, and the second die being configured for an auxiliary function. It can be understood that the computation function typically requires higher performance, which can facilitate the migration of the die configured for the computation function to an advanced fabrication and packaging processes, and the auxiliary function typically requires lower performance, which allows the die configured of the auxiliary function to remain on a more conservative fabrication and packaging processes to save cost and improve yield.

In one embodiment (including but not limited to any of the aforementioned embodiments), a fabrication process accommodating each function of die is positively correlated with a first performance demand for said each function of die, where the first performance demand includes one or more of demands on rate, power consumption, and bandwidth. It can be understood that different fabrication processes typically meet different demands on computing rate, power consumption and bandwidth, and this embodiment does not impose specific restriction thereon.

In one embodiment (including but not limited to any of the aforementioned embodiments), a packaging process that accommodates each function of die is positively correlated with a second performance demand for said each function of die, where the second performance demand includes at least one of demands on rate and bandwidth. Different packaging processes typically meet different demands on computing rate, power consumption and bandwidth requirements, and this embodiment does not impose specific restriction thereon.

In one embodiment (including but not limited to any of the aforementioned embodiments), more than one first die is stacked on the interposer based on the first packaging process, and at least one second die is tiled on the interposer based on the second packaging process.

For example, FIG. 2 shows a hybrid packaging architecture, in which multiple first dies are stacked and packaged in a 3D packaging architecture, with high-speed interconnections between the first dies being achieved via TSVs; then the at least one second die is interconnected to the first dies through the interposer. The interposer is connected to the substrate through bumps, thereby finally achieving a 2.5D+3D hybrid packaging. The interposer is a silicon-based substrate made of silicon and organic materials, configured to connect the upper and lower layers via TSVs and soldered to the traditional 2D packaging substrate through solder balls. In advanced packaging architectures, it serves as an electrical conduit for multi-chip modules to route electrical signals, achieving interconnections between chips as well as interconnection with the packaging substrate. The TSV serving as a bridge between a plurality of dies and circuit boards are the key implementation technology for 2.5D packaging solutions, where copper is filled in the wafer to provide vertical interconnection penetrating through the silicon wafer die, achieving electrical connection between opposing sides of the wafer with the shortest path. In this way, a hybrid packaging technology may be used to achieve high-density packaging of the first and second dies.

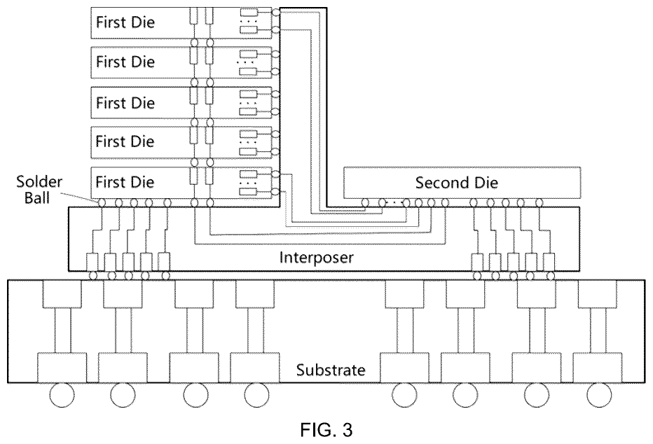

In one embodiment, referring to FIG. 3, the interposer includes a main portion disposed on the upper side of the substrate and a branch portion extended along a direction in which a plurality of dies are stacked, where at least one first die is stacked on the upper side of the main portion, and each laterally extended to be connected to the branch portion. In this way, a more innovative hybrid packaging solution is provided, which can ensure higher clock signal accuracy because the route length from each first die to the interposer is consistent.

Specifically, the interposer may be an inverted T-shaped interposer.

For example, taking the clock signal as an example, if it is transmitted by the first dies step by step through the interconnections between TSVs, it is bound to cause loss in quality of the transmitted signal, and it is necessary to add a lot of CELLs with strong driving capabilities at the exit positions of the first dies. In view of this, referring to FIG. 3, the interposer may be designed as a special-shaped interposer in this embodiment, such as an inverted T-shaped interposer. The height of the vertical portion of the special-shaped interposer may be set to be consistent with the height of the 3D package. Then the clock signal is connected to the interposer through the bumps (Macrobumps) by extending pins horizontally. There are only transmission lines inside the interposer, so that the line loss of important signals such as clocks will be minimized, which can reduce signal delay, decrease capacitance/inductance, and achieve low power consumption, high-speed communication and increased bandwidth between chips. Other signals between the first dies may still be transmitted via TSV.

In one embodiment, the first packaging process is a 3D packaging process or an advanced packaging process beyond the 3D packaging process, and the second packaging process is a 2.5D packaging process.

Based on the same or similar inventive concept, the disclosed embodiment also provides a manufacturing method for a chip, which is specifically the manufacturing method for a chip described in the above embodiment.

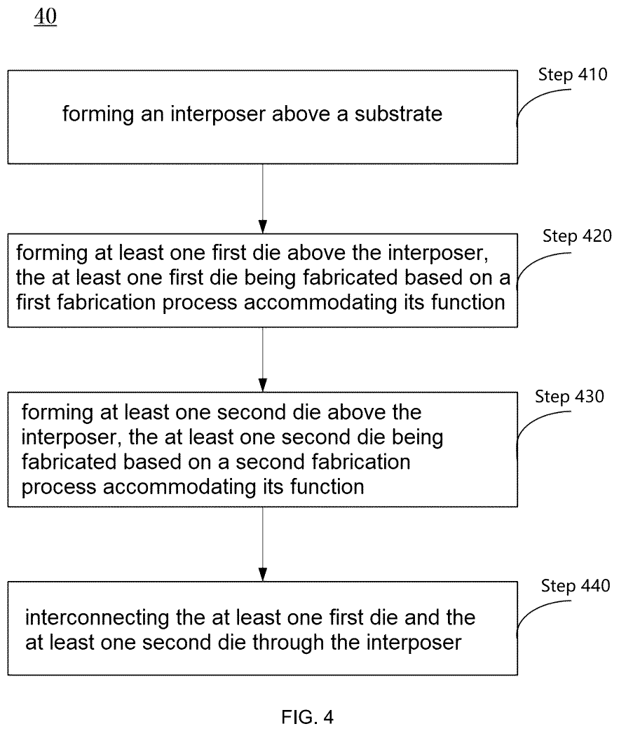

FIG. 4 shows a flow chart of a manufacturing method for a chip according to an embodiment of the present disclosure. It should be understood that method 40 may further include one or more additional steps not shown and/or may omit one or more steps shown, and the scope of the present disclosure is not limited in this respect.

Step 410: an interposer is formed above the substrate;

Step 420: at least one first die is formed above the interposer, the at least one first die being fabricated based on a first fabrication process accommodating its function;

Step 430: at least one second die is formed above the interposer, the at least one second die being fabricated based on a second fabrication process accommodating its function; and

Step 440: the at least one first die and the at least one second die are interconnected through the interposer.

In one embodiment, before the above step 420, the method further includes packaging the at least one first die based on a first packaging process accommodating the function of the at least one first die; and before the above step 430, packaging the at least one second die based on a second packaging process accommodating the function of the at least one second die.

Specifically, the at least one first die is configured for a computation function. It can be understood that the higher the computation demand, the higher the demands on various performances such as bandwidth, rate, power consumption. Therefore, a die configured for the computation function typically requires a higher level of fabrication process or packaging process.

Specifically, the at least one second die is configured for an auxiliary function. It can be understood that any function that does not require high-intensity computing can be regarded as the auxiliary function. For example, the at least one second die includes one or more of: a control-function die configured for chip control; a test-function die configured for chip testing; and an interface-function die configured to enable an I/O interface.

In one embodiment, a fabrication process accommodating each function of die is positively correlated with a first performance demand for said each function of die, where the first performance demand includes at least one of demands on rate, power consumption, and bandwidth.

In one embodiment, a packaging process accommodating each function of die is positively correlated with a second performance demand for said each function of die, where the second performance demand includes at least one of demands on rate and bandwidth.

In one embodiment, the above step 420 further includes stacking the at least one first die above the interposer based on the first packaging process; the above step 430 further includes tiling the at least one second die above the interposer based on the second packaging process.

In one embodiment, the interposer includes a main portion disposed on the upper side of the substrate and a branch portion disposed along a direction in which a plurality of dies are stacked, where the at least one first die is stacked on the upper side of the main portion, and each laterally extended to be connected to the branch portion.

In one embodiment, the interposer is an inverted T-shaped interposer.

In one embodiment, the first packaging process is a 3D packaging process or an advanced packaging process beyond the 3D packaging process, and the second packaging process is a 2.5D packaging process.

It should be noted that the manufacturing method for a chip in the embodiment of the present disclosure achieves the same effect and function as the aforementioned chip, and will not be repeated here.

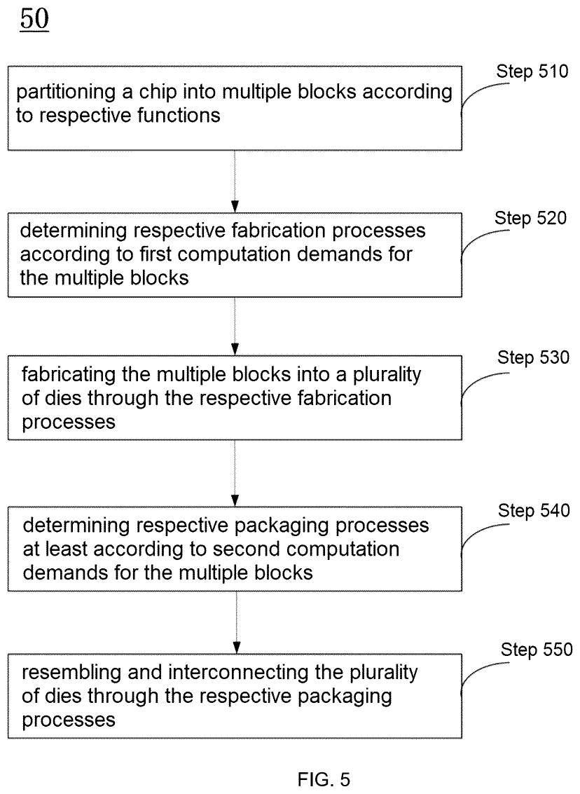

FIG. 5 shows a flowchart for implementing a hybrid packaging method for a chip according to an embodiment of the present disclosure. It should be understood that the method 50 may further include one or more additional steps not shown and/or one or more additional steps shown may be omitted, and the scope of the present disclosure is not limited in this respect.

Step 510: the chip is partitioned into multiple blocks according to respective functions.

Specifically, in the chip design stage, the chip can be partitioned into blocks according to respective functions. Partitioning of the chip into blocks responsible for different functions facilitates migration of the key functional blocks of the chip to advanced processes, while allowing the auxiliary blocks to remain on the more conservative original process nodes.

For example, referring to FIG. 5, the designed complete chip may be partitioned into different partitions such as computation block, control block, interface block, and test block, which are responsible for different chip functions respectively. This embodiment does not specifically limit the functions and number of partitioned blocks.

Step 520: respective fabrication processes are determined according to first computation demands for the multiple blocks.

Specifically, the fabrication process corresponding to each block may be proportional to its first computation demand, that is, the higher the first computation demand, the more advanced the fabrication process used. The first computation demand may include demands on various performances such as bandwidth, rate, and power consumption. The fabrication processes accommodating the first computation demands on different performances are also different. The fabrication process to be used can be comprehensively considered based on the first computation demands on these performances.

Step 530: the multiple blocks are fabricated into a plurality of dies through the respective fabrication processes.

Specifically, once the aforesaid block partitioning and fabrication process selection are completed, each block may be independently designed and fabricated into a small chip. Optionally, for general blocks in the chip, such as interface and test blocks, existing functional chip IPs may be reused without designing dedicated functional chip IPs in the entire chip.

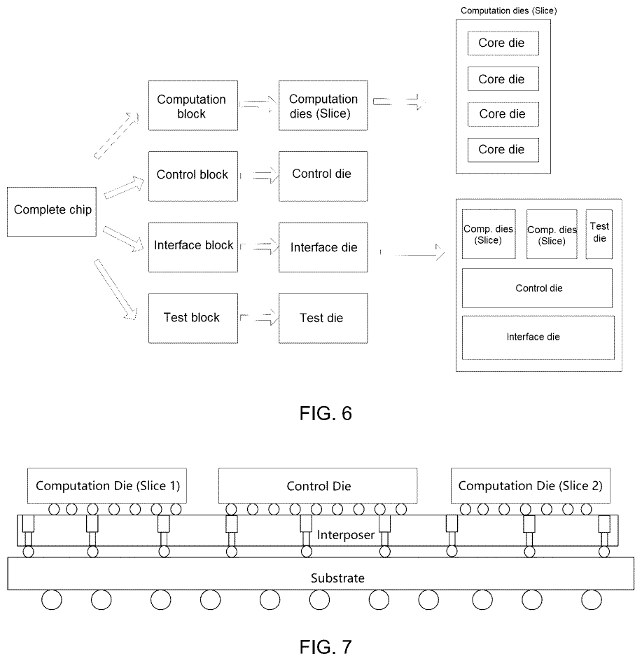

For example, referring to FIG. 6, it is assumed that the computation block is responsible for large-scale integrated computation, and thus requirements for performances such as interconnection bandwidth, rate, and power consumption are very high. In this case, a more advanced fabrication process such as TSMC's 5 nm process may be chosen for fabrication. Furthermore, stdcell such as ELVT may be adopted to enhance the chip's speed and reduce power consumption. Unlike the computation block, the control block has no special requirement on rate in its design, but the overall chip power consumption needs to be considered, thus a less advanced fabrication process such as TSMC's 7 nm may be adopted. The interface and test blocks have much lower demands on computation, thus a more stable and mature fabrication process may be chosen, such as Samsung's 14 nm and SMIC's 12 nm, etc.

Step 540: respective packaging processes corresponding to the multiple blocks for the plurality of dies are determined at least according to second computation demands for the multiple blocks.

Step 550: the plurality of dies are resembled and interconnected through the respective packaging processes.

Specifically, this embodiment adopts a hybrid packaging approach, which can capitalize on different benefits of various packaging processes, and allows adaptive adoption of a packaging process suitable for each die, thereby significantly improving the yield.

For example, referring to FIG. 7, a 2.5D packaging process may be adopted to package a die with a lower computation demand to save cost, and a 3D packaging process or a more advanced packaging process (for example, 4D packaging, 5D packaging) may be adopted to package other dies with higher computation demands to achieve better technical effects. The hybrid packaging approach enable full utilization of the various benefits of different packaging processes. The embodiment of the present disclosure does not specifically limit the packaging process used for each die, and any differentiated packaging process can be used for packaging as long as it can meet the chip packaging requirements.

In this embodiment, a large chip is partitioned into smaller dies, followed by integrating multiple homogeneous or heterogeneous dies into a unified design through an improved advanced packaging architectures, such that for distinct blocks, more suitable fabrication and packaging processes for dies are applied and interconnections between dies are implemented with improved efficiency respectively, thereby improving the computing power of the manufactured chip, and achieving balanced optimization across bandwidth density, latency, power consumption, and cost thereof, thus capitalizing on the benefits of reduced bandwidth density, power consumption, and cost, while effectively mitigating the need for continuous die size scaling.

In one embodiment, the multiple blocks may include a computation block for implementing integrated computation and a functional block for implementing an auxiliary function. In this embodiment, the entire chip is partitioned into a computation block with a higher computation demand and a functional block with a lower computation demand, which can facilitate the migration of the chip's computation block to advanced fabrication and packaging processes, while allowing the functional block to remain on more conservative fabrication and packaging processes to save cost and improve yield.

In one embodiment, in order to achieve the packaging effect of a computation block with a higher computation demand, when the computation block includes multiple computing cores, the computation block can be further partitioned into multiple computation sub-blocks corresponding to the multiple computing cores. Thus, the core dies corresponding to the computation sub-blocks can be packaged in a stacked manner, saving space and accommodating demands on bandwidth density, delay, and power consumption of the computation block better.

In one embodiment, the functional block includes one or more of: a control block for chip control; a test block for chip testing; and an interface block for enabling an I/O interface.

Optionally, for the various blocks in the functional block, differentiated fabrication processes may be adopted based on their respective first computation demands, and differentiated packaging processes may be adopted based on their respective second computation demands. For example, unlike the computation block, the control block has no special requirement on rate in its design, but the overall chip power consumption needs to be considered, thus a relatively moderate fabrication process may be adopted. In contrast, the interface and test blocks have much lower demands on computation, thus a more stable and mature fabrication process may be chosen.

Optionally, as to the functional block, since redesigning the entire chip is cost-prohibitive, for general chip blocks like test and interface blocks, existing block-design chips may be reused, thus saving costs and speeding up development.

In one embodiment, the above first computation demand includes one or more of demands on rate, power consumption, and bandwidth for each block. Different fabrication processes typically meet different demands on computing rate, power consumption and bandwidth, and this embodiment does not impose specific restriction thereon.

In one embodiment, the second computation demand includes a demand on rate and/or a demand on bandwidth for each block. Different packaging processes typically meet different demands on computing rate and bandwidth, and this embodiment does not impose specific restriction thereon.

In one embodiment, the packaging process for each die may also be determined according to a size of each die and/or a packaging complexity for resembling and interconnecting the plurality of dies. That is, in addition to considering the computation demands for the corresponding blocks, the size of each die and the packaging complexity for the entire chip may also be comprehensively considered for the selection of the packaging process for each die.

For example, as shown in FIGS. 6 and 7, considering that the plurality of dies corresponding to the computation block have requirements for bandwidth and rate, 3D packaging can be chosen and implemented via TSV. For the other dies corresponding to the control, test and interface blocks, considering the packaging complexity and the overall chip area (excessive size impacts the PCB and product), 2.5D packaging may be chosen, and finally the small chips of the above two packaging types may be interconnected through the interposer on the substrate.

In one embodiment, in step 500, a plurality of dies corresponding to first blocks may be stacked through a first packaging process on the upper side of the interposer; and one or more dies corresponding to second blocks may be tiled through a second packaging process on the upper side of the interposer; finally, the interconnection between the dies is implemented through the interposer connected to the substrate.

The first packaging process may be a 3D packaging process and/or an advanced packaging process beyond the 3D packaging process, and the second packaging process may be a 2.5D packaging process.

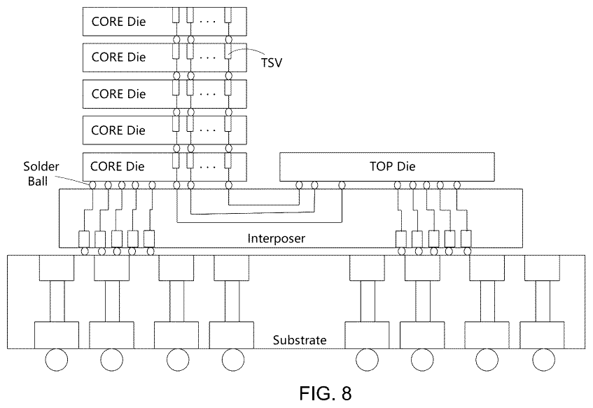

For example, FIG. 8 shows a hybrid packaging architecture, where multiple core dies are stackedly packaged in a 3D packaging structure, and high-speed interconnections between the core dies are implemented via TSVs; then the control die (TOP Die) is interconnected with the core dies through the interposer. The interposer is connected to the substrate through bumps, and finally a 2.5D+3D hybrid packaging is achieved. The interposer is a silicon-based substrate made of silicon and organic materials, configured to connect the upper and lower layers via TSVs and soldered to the traditional 2D packaging substrate through solder balls. In advanced packaging architectures, it serves as an electrical conduit for multi-chip modules to route electrical signals, achieving interconnections between chips as well as interconnection with the packaging substrate. The TSV serving as a bridge between a plurality of dies and circuit boards are the key implementation technology for 2.5D packaging solutions, where copper is filled in the wafer to provide vertical interconnection penetrating through the silicon wafer die, achieving electrical connection between opposing sides of the wafer with the shortest path.

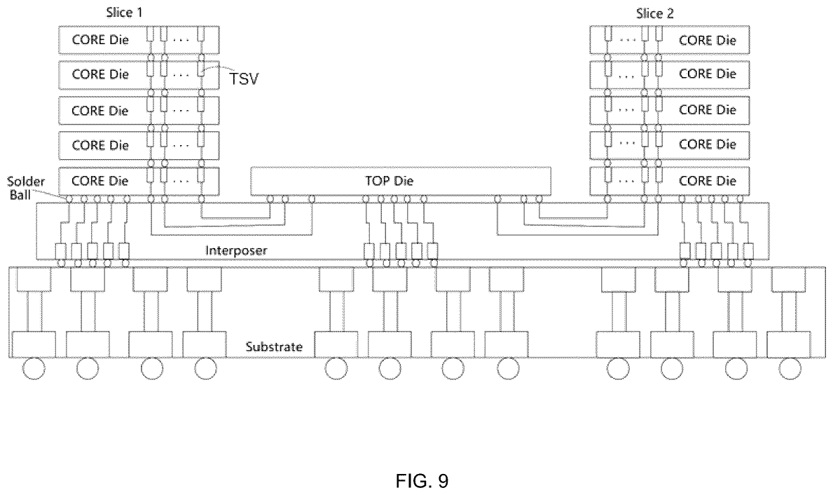

For another example, FIG. 9 shows another hybrid packaging architecture, where multiple core dies are arranged into different columns (Slices) through 3D stacking, and interconnections between multiple core dies are implemented via TSVs, thereafter different columns (Slices) are connected to the interposer through bumps. Similarly, the control die (TOP Die) is connected to the substrate through the interposer in a 2.5D packaging structure. Therefore, the hybrid packaging solution allow for leveraging both the area efficiency of 3D packaging and the cost advantage of 2.5D packaging.

In one embodiment, a special-shaped interposer may be used, which has a main portion disposed on the upper side of the substrate and a branch portion extended along a direction in which a plurality of dies are stacked, where the plurality of dies corresponding to the first block are stacked on the upper side of the main portion, and extended horizontally to be connected to the branch portion. In this way, a more innovative hybrid packaging solution is provided, which can ensure higher clock signal accuracy.

In one embodiment, the special-shaped interposer may be formed as an inverted T-shaped interposer.

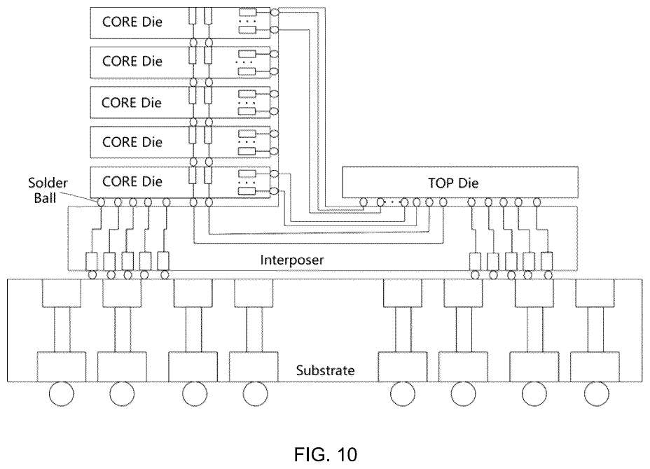

For example, taking the clock signal as an example, since the algorithm chip has extremely high requirements for the clock signal of the core dies. If signals are transmitted through TSVs via interconnections between the core dies step by step, it is bound to cause loss in quality of the transmitted signal, and it is necessary to add a lot of CELLs with strong driving capabilities at the exit positions of the core dies. In view of this, referring to FIG. 10, the interposer may be designed as a special-shaped interposer in this embodiment, such as an inverted T-shaped interposer. The height of the vertical portion of the special-shaped interposer may be set to be consistent with the height of the 3D package. Then the clock signal is connected to the interposer through the bumps (Macrobumps) by extending pins horizontally. There are only transmission lines inside the interposer, so that the line loss of important signals such as clocks will be minimized, which can reduce signal delay, decrease capacitance/inductance, and achieve low power consumption, high-speed communication and increased bandwidth between chips. Other signals between the core dies may still be transmitted via TSVs.

In one embodiment, the chip is a high-computing power chip.

It should be noted that the steps not described in detail in this embodiment can refer to the description of the relevant steps in the embodiment shown in FIG. 5, and will not be repeated here.

In the description of this specification, references to the terms such as “some possible embodiments”, “some embodiments”, “example”, “specific example”, or “some examples” mean that the specific features, structures, materials or characteristics described in connection with such embodiments or examples are included in at least one embodiment or example of the present disclosure, while these terms do not necessarily refer to the same embodiment or example. Moreover, the described specific features, structures, materials or characteristics may be combined in any one or more embodiments or examples in any suitable manner. In addition, without contradiction, a person skilled in the art may combine and integrate the different embodiments or examples described in this specification as well as the features of the different embodiments or examples.

Regarding the flowchart of the embodiment of the present disclosure, certain operations are described as different steps performed in a certain order. Such a flow chart is illustrative rather than restrictive. Certain steps described herein may be grouped together and performed in a single operation, or certain steps may be divided into multiple sub-steps, and certain steps may be performed in an order different from that shown herein. The various steps shown in the flowchart may be implemented in any way by any circuit structure and/or tangible mechanism (for example, by software running on a computing device, hardware (for example, a logical function implemented by a processor or chip), etc., and/or any combination thereof).

Based on the same technical concept, the embodiment of the present disclosure also provides a hybrid packaged chip, which is a chip manufactured using the packaging method described in the above embodiment.

Based on the same or similar technical concept, the embodiment of the present disclosure also provides a hybrid packaged chip. Referring to FIGS. 3 to 6, the hybrid packaged chip includes a substrate, an interposer disposed above the substrate, and a plurality of dies disposed above the interposer; where the plurality of dies are fabricated through different fabrication processes, and resembled and interconnected above the interposer through different packaging processes.

In one embodiment, the plurality of dies correspond to multiple blocks partitioned according to respective functions in the chip, where the plurality of dies are fabricated through different fabrication processes according to the first computation demands for the corresponding blocks, and resembled and interconnected above the interposer through different packaging processes according to the second computation demands for the corresponding blocks.

Specifically, the fabrication process corresponding to each block can be proportional to its first computation demand, that is, the higher the first computation demand, the more advanced the fabrication process used. The first computation demand can include computation demands of multiple dimensions such as bandwidth, rate, power consumption, etc. The fabrication process accommodated by the first computation demands of different dimensions is also different. The fabrication process used can be comprehensively considered based on the first computation demands of these dimensions. The packaging process corresponding to each block can be proportional to its second computation demand, that is, the higher the second computation demand, the more advanced the packaging process used. The second computation demand can include computation demands of multiple dimensions such as bandwidth, rate, etc.

In one embodiment, the fabrication process for each die is determined according to one or more of demands on rate, power consumption, and bandwidth for the corresponding block of each die.

In one embodiment, the packaging process for each die is determined according to one or more of a demand on rate and/or a demand on bandwidth of the corresponding block of each die, a size of each die, and a packaging complexity for resembling and interconnection.

In one embodiment, the multiple blocks include a computation block for implementing integrated computing and a functional block for implementing auxiliary functions. Partitioning the entire chip into a computation block with relatively high computation demands and a functional block with relatively low computation demands can facilitate the migration of the computation block of the chip to an advanced process and an advanced packaging process, while the functional block maintains a more conservative process and packaging process to save costs and improve yield.

In one embodiment, when the computation block includes multiple computing cores, the computation block is further partitioned to obtain multiple computation sub-blocks corresponding to the multiple computing cores. Thus, the core dies corresponding to the equivalent computation sub-blocks can be packaged in a stacking manner, saving space and better accommodating the bandwidth density, delay, and power consumption requirements of the computation block.

In one embodiment, the functional block includes one or more of a control block for chip control; a test block for chip testing; and an interface block for enabling an I/O interface.

Optionally, the various blocks in the above-mentioned functional blocks can also adopt differentiated fabrication processes based on their respective first computation demands, and differentiated packaging technologies based on their respective second computation demands. For example, the design of the control block has no speed requirements relative to the computation block, but the overall chip power consumption needs to be considered, so a relatively moderate fabrication process can be used. In contrast, the computation demands of the interface block and the test block are relatively lower, so a more stable and mature fabrication process can be selected.

Optionally, in the above-mentioned functional blocks, since the development cost of redesigning the entire chip with full coverage is high, for chip common blocks such as test blocks and/or interface blocks, the existing block design chip can be reused, thereby effectively saving costs and speeding up time.

In one embodiment, for the plurality of dies resembled and interconnected above the interposer through different packaging processes, more than one die is stacked on the upper side of the interposer through a first packaging process; and/or one or more dies are tiled on the upper side of the interposer through a second packaging process; and interconnections between dies are established through the interposer connected to the substrate.

In one embodiment, the first packaging process is a 3D packaging process and/or an advanced packaging process beyond the 3D packaging process, and the second packaging process is a 2.5D packaging process.

In one embodiment, a special-shaped interposer is utilized, where the special-shaped interposer has a main portion disposed on the upper side of the substrate and a branch portion extended along a direction in which more than one die are stacked, the more than one die being stacked on the upper side of the main portion, and extended laterally to be connected to the branch portion.

In one embodiment, the special-shaped interposer is an inverted T-shaped interposer.

In one embodiment, the chip is a high-computing power chip.

It should be noted that the hybrid packaged chip in the embodiment of the present disclosure achieves the same effect and function as the aforementioned method, which will not be described here.

Although the spirit and principle of the present disclosure have been described with reference to several specific embodiments, it should be understood that the present disclosure is not limited to the disclosed specific embodiments, and the division of various aspects does not mean that the features in these aspects cannot be combined for benefit, and such division is only for the convenience of expression. The present disclosure is intended to cover various modifications and equivalent arrangements included in the spirit and scope of the appended claims.

1. A chip, comprising a substrate and an interposer disposed above the substrate, and further comprising:
at least one first die disposed above the interposer, the at least one first die being fabricated based on a first fabrication process accommodating a function of the at least one first die; and
at least one second die disposed above the interposer, the at least one second die being fabricated based on a second fabrication process accommodating a function of the at least one second die,
wherein the at least one first die and the at least one second die are interconnected through the interposer.

2. The chip according to claim 1, wherein the at least one first die is packaged based on a first packaging process accommodating the function of the at least one first die, and the at least one second die is packaged based on a second packaging process accommodating the function of the at least one second die.

3. The chip according to claim 1, wherein the at least one first die is configured for a computation function.

4. The chip according to claim 1, wherein the at least one second die is configured for an auxiliary function.

5. The chip according to claim 1, wherein the at least one second die comprises one or more of: a control-function die configured for chip control; a test-function die configured for chip testing; and an interface-function die configured to enable an I/O interface.

6-8. (canceled)

9. The chip according to claim 1, wherein a fabrication process accommodating each function of die is positively correlated with a first performance demand for said each function of die, the first performance demand comprising at least one of demands on rate, power consumption, and bandwidth.

10. The chip according to claim 1, wherein a packaging process accommodating each function of die is positively correlated with a second performance demand for said each function of die, the second performance demand comprising at least one of demands on rate and bandwidth.

11. The chip according to claim 1, wherein the at least one first die is stacked on the interposer based on a first packaging process, and the at least one second die is tiled on the interposer based on a second packaging process.

12. The chip according to claim 5, wherein the interposer comprises a main portion disposed on an upper side of the substrate and a branch portion extended along a direction in which a plurality of dies are stacked, the at least one first die being stacked on an upper side of the main portion, and each of the at least one first die being laterally extended to be connected to the branch portion.

13. The chip according to claim 1, wherein the interposer is an inverted T-shaped interposer.

14. The chip according to claim 2, wherein the first packaging process is a 3D packaging process or an advanced packaging process beyond the 3D packaging process, and the second packaging process is a 2.5D packaging process.

15-45. (canceled)

46. A chip, comprising a substrate, an interposer disposed above the substrate, and a plurality of dies disposed above the interposer, wherein the plurality of dies are configured for multiple functions of the chip and fabricated through fabrication processes respectively accommodating the multiple functions.

47. The chip according to claim 46, wherein the plurality of dies are packaged through packaging processes respectively accommodating the multiple functions.

48. The chip according to claim 46, wherein a fabrication process accommodating each function is positively correlated with a performance demand for said each function.

49. The chip according to claim 47, wherein a packaging process accommodating each function is positively correlated with a performance demand for said each function.

50. The chip according to claim 48, wherein the multiple functions comprise a computation function and an auxiliary function.

51. The chip according to claim 50, wherein at least one die configured for the computation function is fabricated through a first fabrication process accommodating the performance demand for the computation function, and at least one die configured for the auxiliary function is fabricated through a second fabrication process accommodating the performance demand for the auxiliary function.

52. The chip according to claim 51, wherein the chip comprises at least one core die configured for the computation function and at least one auxiliary die configured for the auxiliary function, the at least one core die being fabricated through the first fabrication process, and the at least one auxiliary die being fabricated through the second fabrication process.

53. The chip according to claim 52, wherein the at least one core die is packaged through a first packaging process, and the at least one auxiliary die is packaged through a second packaging process.

54. The chip according to claim 52, wherein the at least one auxiliary die comprises one or more of: a control-function die configured for chip control; a test-function die configured for chip testing; and an interface-function die configured to enable an I/O interface.

55-60. (canceled)
